(19) United States
(12) Patent Application Publication
(10) Pub. No.: US 2010/0134968 A1
(43) Pub. Date: Jun. 3, 2010

(54) MOBILE TERMINAL DEVICE

(75) Inventors: Hidekatsu Kobayashi, Kawasaki (JP); Takashi Suzuki, Kawasaki (JP); Ryo Hattori, Kawasaki (JP); Kouki Murakami, Kawasaki (JP); Hidehiko Hiduka, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 12/579,641

(22) Filed: Oct. 15, 2009

(30) Foreign Application Priority Data
Nov. 28, 2008 (JP) 2008-305600

(51) Int. Cl. H05K 5/02

(52) U.S. Cl. 361/679.26

(57) ABSTRACT

A mobile terminal device includes a display section; a housing including a frame member forming an opening for accommodating the display section; a transparent plate member disposed over the display section; a metal panel member disposed over the frame member so as to expose the transparent plate member; and an adhesive member having an adhesive obverse surface and an adhesive reverse surface placed between the frame member and each of the transparent plate member and the metal panel member, the adhesive reverse surface being adhesively fixed to the frame member, the adhesive obverse surface being adhesively fixed to the transparent plate member and the metal panel member.

### CROSS-REFERENCE TO RELATED APPLICATION

This application is based upon and claims the benefit of priority of the prior Japanese Patent Application No. 2008-305600, filed on Nov. 28, 2008, the entire contents of which are incorporated herein by reference.

### FIELD

The embodiments discussed herein are related to a mobile terminal device.

### BACKGROUND

In response to demands for reduction in size and thickness, recent mobile telephones have a double folding structure in which two housings, namely, a fixed housing and a movable housing are connected via a connecting portion having a hinge structure (for example, see Japanese Laid-open Patent Publication No. 2005-252343).

Such a mobile telephone includes not only a large LDC (Liquid Crystal Display) section provided on a movable front case of the movable housing, but also a display section that allows information, such as time, to be displayed on a front panel plate of a movable rear case even when the mobile telephone is in a closed state.

This time display provided on the front panel plate of the movable rear case allows the user of the mobile telephone to check information, such as time, without opening the mobile telephone.

Such a conventional mobile telephone is of a double folding type in which the two housings to be opened and closed on the hinge portion are molded from a plastic material or the like. There is therefore an increasing demand for a structure having strength, for example, opening and closing durability against opening and closing of the mobile telephone.

When the information display section for displaying the time is provided on the front panel plate of the movable rear case in the movable housing of the mobile telephone, as described above, a window is provided so that the user views the information display section therethrough. More specifically, it is preferably to form a rectangular opening as a window in an outer resin case serving as the front panel plate of the movable rear case. Hence, the opening reduces the strength of the outer resin case.

On the other hand, when the front panel plate is not formed of the resin material, but is formed by a metal member having high strength, such as a metal panel, it is impossible to view the time display section provided under the metal member.

To view the time display section or the like provided under the front panel plate, it is conceivable to provide a transparent panel, that is, a transparent plate member, separately from the metal front panel plate. In this case, the metal front panel plate and the transparent plate member are assembled and fixed independently. More specifically, the display panel plate and the transparent plate member are fixed one on the other by bonding with a double-faced adhesive member such as a double-faced tape. Since this increases the number of components, thickness reduction of the mobile telephone is impossible. Further, the increase in number of components is also a problem from the viewpoint of waterproofness.

### SUMMARY

According to an aspect of the invention, a mobile terminal device includes a display section; a housing including a frame member forming an opening for accommodating the display section; a transparent plate member disposed over the display section; a metal panel member disposed over the frame member so as to expose the transparent plate member; and an adhesive member having an adhesive obverse surface and an adhesive reverse surface placed between the frame member and each of the transparent plate member and the metal panel member, the adhesive reverse surface being adhesively fixed to the frame member, the adhesive obverse surface being adhesively fixed to the transparent plate member and the metal panel member.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a plan view illustrating an open state of a mobile telephone according to an embodiment;

FIG. 2 is a side view illustrating the open state of the mobile telephone;

FIG. 3 is a side view illustrating a closed state of the mobile telephone;

FIG. 4 is a top view of a front panel plate of the mobile telephone;

FIG. 5 is a plan view of a transparent plate member;

FIG. 6 is a plan view of a metal panel member;

FIG. 7 is an enlarged cross-sectional view, taken along line A-A in FIG. 4;

FIG. 8 is a perspective view of a movable housing and a double-faced adhesive member; and

FIG. 9 is a view illustrating how to fix the transparent plate member and the metal panel member to a movable rear case.

### DESCRIPTION OF EMBODIMENTS

A mobile terminal device according to a preferred embodiment will be described in detail below with reference to the attached drawings. The following embodiment is an application example to a mobile telephone serving as a mobile terminal device. The present invention is not limited by the embodiment.

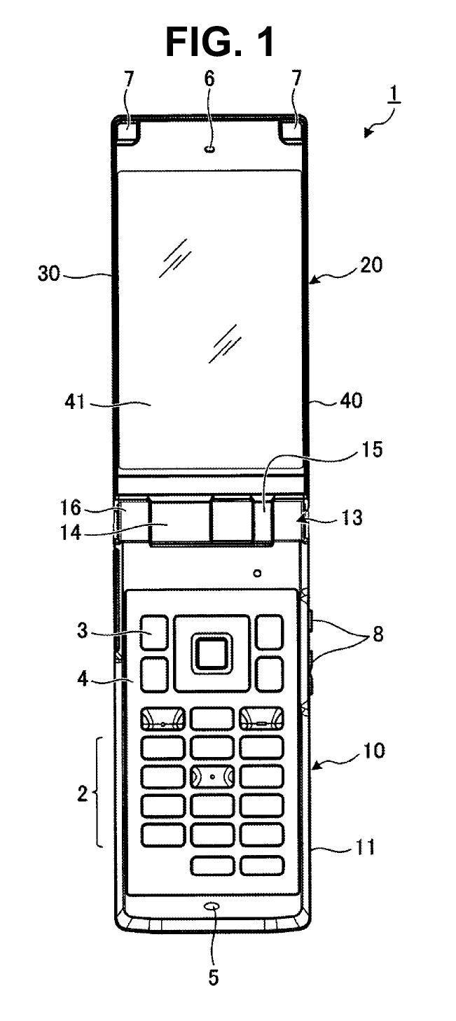

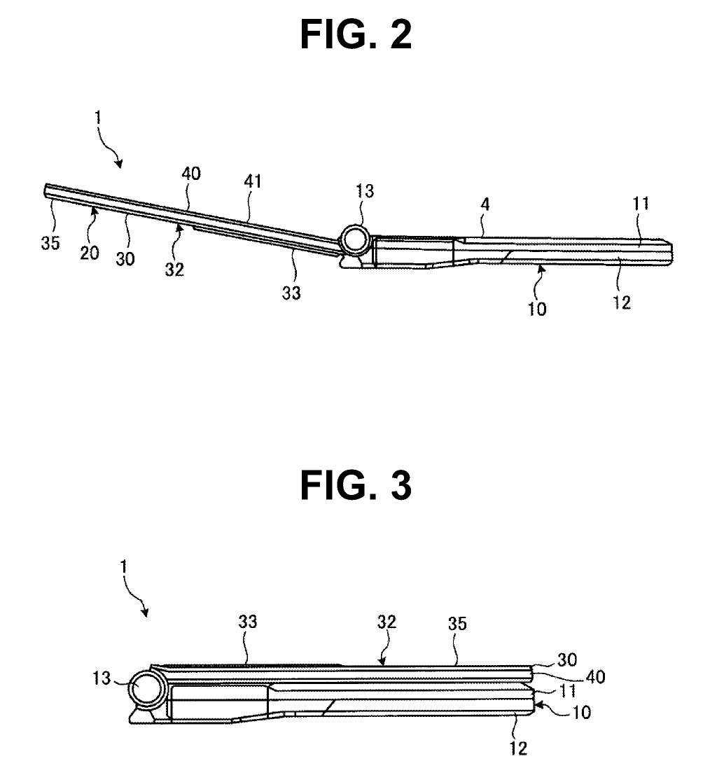

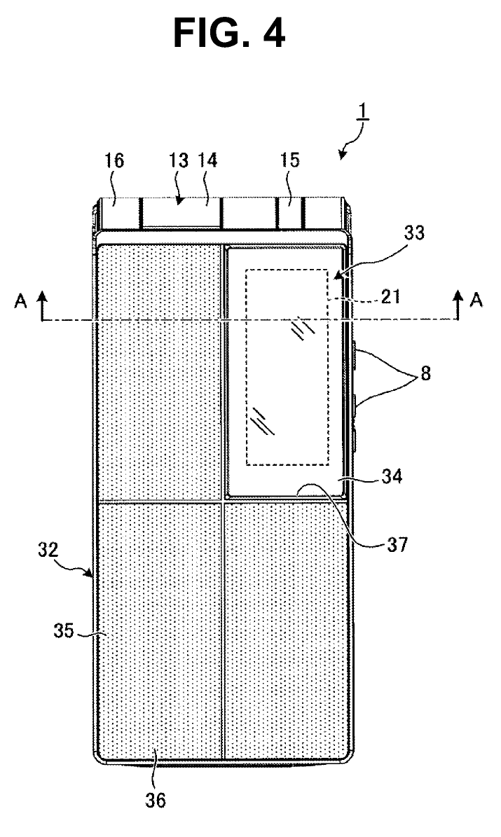

FIG. 1 is a plan view illustrating an open state of a mobile telephone 1 according to the embodiment. FIG. 2 is a side view illustrating the open state of the mobile telephone 1, and FIG. 3 is a side view illustrating a closed state of the mobile telephone 1. FIG. 4 is a top view illustrating a front panel plate of the mobile telephone 1.

As illustrated in FIGS. 1 to 3, the mobile telephone 1 includes a fixed housing 10 and a movable housing 20 each having a palm size. The fixed housing 10 and the movable housing 20 are assembled together by a connecting hinge portion 13 so as to be opened and closed.

That is, in the mobile telephone 1, the fixed housing 10 used for transmission and having various operation keys, for example, key switches 2 including ten keys and function keys 3, and the movable housing 20 having a size substantially equal to the size of the fixed housing 10 and including an LCD module (not illustrated) are connected in a folding manner by the connecting hinge portion 13. Each of the fixed housing 10 and the movable housing 20 is shaped like a thin box and is formed of, for example, a magnesium alloy that is light and strong.

In the connecting hinge portion 13, movable hinge portions 14 and 15 provided at an end of a movable rear case 30 and a fixed hinge portion 16 provided at an end of a fixed front case 11 are assembled together in a manner such as to turn on a pivot shaft (not illustrated). This allows the movable rear case 30 of the movable housing 20 to turn in a predetermined direction.

The fixed housing 10 has a two-part structure including a fixed front case 11 in which an operation panel 4 having various operation keys, such as the key switches 2, is provided, and a fixed rear case 12 provided on the rear side of the fixed front case 11.

The fixed front case 11 is provided with the operation panel 4 and the function keys 3 described above, and a mouthpiece 5 incorporating a microphone for converting the voice of the user into electric signals.

A pair of volume keys for adjusting the volume of the radio or the like and a side key, such as a TV key, are provided on a side plate portion of the fixed rear case 12. The fixed front case 11 and the fixed rear case 12 are assembled together by being fixed with screws (not illustrated) at four positions.

The movable housing 20 has a two-part structure including a movable rear case 30 and a movable front case 40. In almost the center of a front surface of the movable front case 40, a large display panel 41 is provided to view the LCD module (not illustrated).

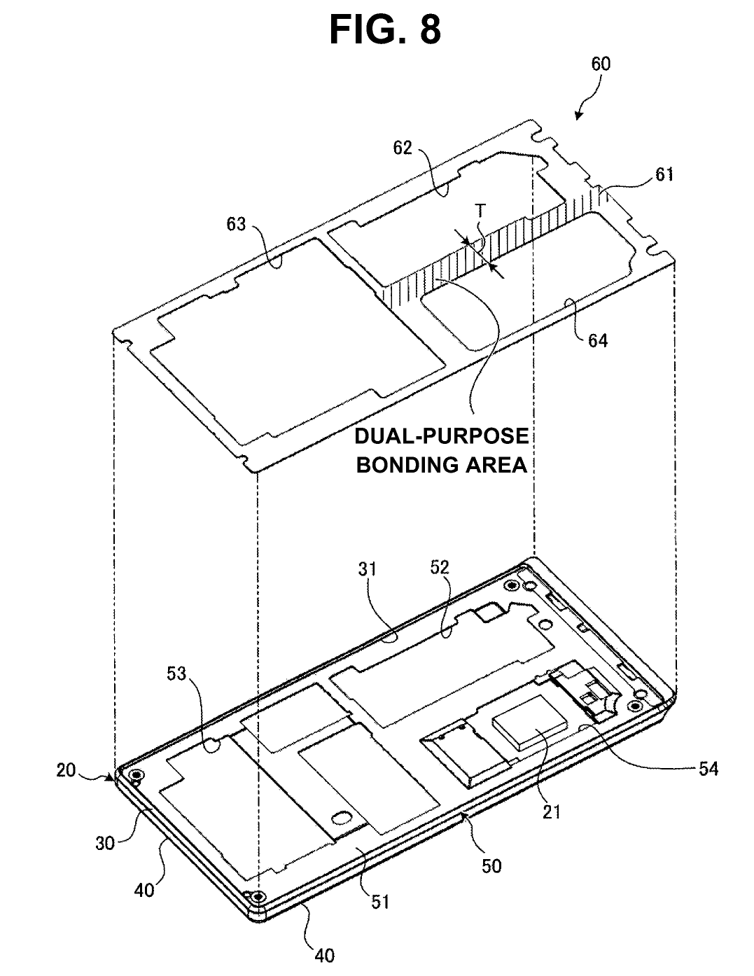

A metal frame plate 50 illustrated in FIG. 8 is provided in the movable rear case 30. A transparent plate member 33 and a metal panel member 35 that constitute a front panel plate 32 are fixed onto a surface of the metal frame plate 50 opposite the movable front case 40 (hereinafter also referred to as an upper surface of the metal frame plate 50) with a double-faced adhesive member 60 therebetween in a state in which the transparent plate member 33 and the metal panel member 35 are combined at a predetermined position.

A time display section 21 serving as a display section for displaying predetermined information is provided on an opposite side of the front panel plate 32, that is, on a rear surface of the transparent plate member 33 that constitutes the front panel plate 32, as illustrated in FIG. 4. Detailed structures and functions of the transparent plate member 33 and the metal panel member 35 made of metal that constitute the front panel plate 32 will be described below.

As illustrated in FIG. 1, an earpiece 6 against which the user of the mobile telephone 1 puts the user's ear to listen to sounds is provided at an end of the display panel 41 in the movable front case 40. The movable rear case 30 and the movable front case 40 are also fixed at four positions by fixing screws (not illustrated). The display panel 41 is provided with concealing covers 7 for the fixing screws.

With reference to FIGS. 4 to 9, detailed descriptions will be given below of the transparent plate member 33 and the metal panel member 35 that are used as the front panel plate 32 of the movable rear case 30 in the movable housing 20.

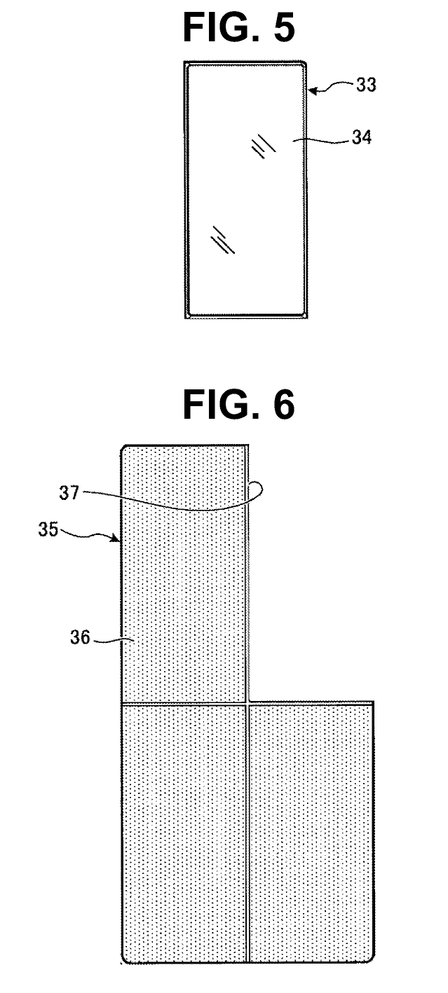

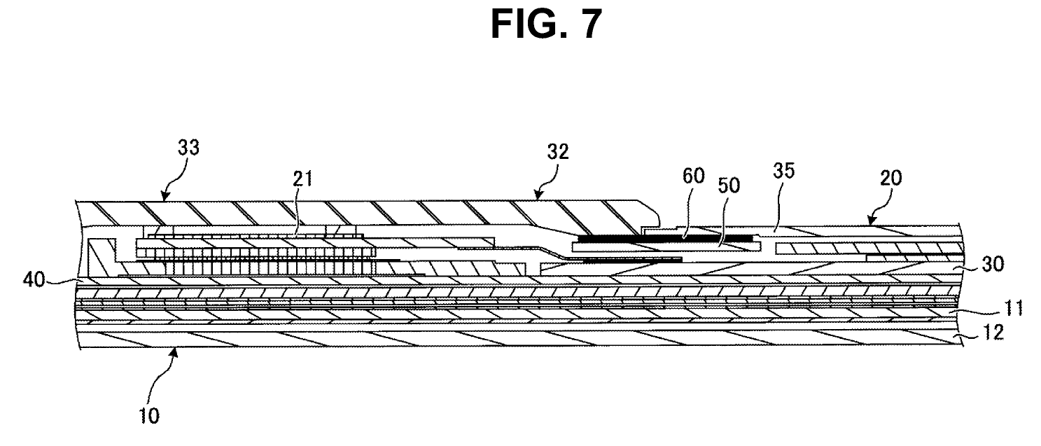

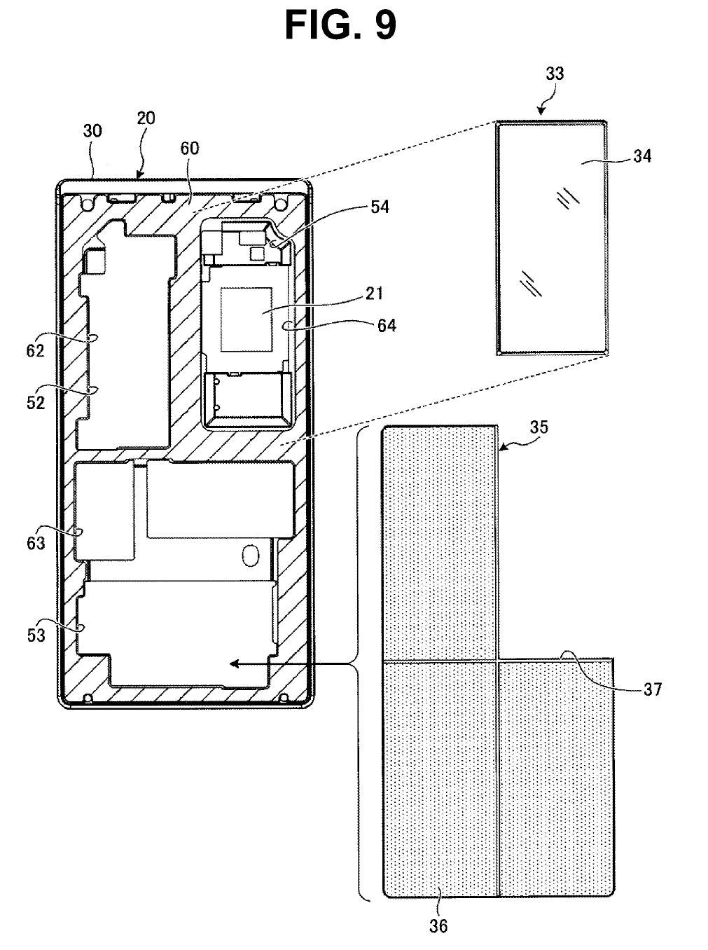

FIG. 4 is a top view of the front panel plate in the mobile telephone 1. FIG. 5 is a plan view of the transparent plate member 33. FIG. 6 is a plan view of the metal panel member 35. FIG. 7 is an enlarged cross-sectional view, taken along line A-A in FIG. 4. FIG. 8 is a perspective view of the movable housing 20 and the double-faced adhesive member 60. FIG. 9 is a view illustrating how to fix the transparent plate member 33 and the metal panel member 35 to the movable rear case 30.

In the mobile telephone 1 of the embodiment, the transparent plate member 33 and the metal panel member 35 that constitute the front panel plate 32 are fixed onto the upper surface of the metal frame plate 50, which is provided in the movable rear case 30 that constitutes the movable housing 20, with the double-faced adhesive member 60 disposed therebetween, so that it is possible to improve the strength and waterproofness of the movable housing 20 in the mobile telephone 1.

That is, the metal frame plate 50 illustrated in FIG. 8 is provided in the movable rear case 30 of the movable housing 20 in the mobile telephone 1, and the transparent plate member 33 for allowing viewing the time display section 21 and the metal panel member 35 having rigidity are fixed in a combined state onto the upper surface of the metal frame plate 50 with the double-faced adhesive member 60. That is, this can improve the strength and waterproofness of the movable rear case 30 of the movable housing 20 in the mobile telephone 1.

Roughly speaking, a resin panel, which has been used as the front panel plate on the upper surface of the movable rear case, is replaced with the metal panel member 35 having strength and made of metal. Further, as illustrated in FIGS. 4 to 9, the transparent plate member 33 for allowing viewing of the time display section 21 for displaying information, which is provided under the front panel plate 32 in the movable rear case 30, is fixed by bonding with the double-faced adhesive member 60 in a state in which the transparent plate member 33 is adjacent to the metal panel member 35 and is combined therewith in the same region.

As illustrated in FIG. 8, the metal frame plate 50 serving as a frame plate member having a shape and size substantially equal to those of the movable rear case 30 is provided in an inner side face portion 31 of the movable rear case 30. As illustrated in FIG. 7, the transparent plate member 33 and the metal panel member 35 that define the front panel plate 32 of the movable housing 20 are fixed onto the upper surface of the metal frame plate 50 by bonding with the double-faced adhesive member 60. That is, the double-faced adhesive member 60 is provided on the metal frame plate 50 with one surface fixed to the upper surface of the metal frame plate 50 by bonding, and the transparent plate member 33 and the metal panel member 35 are fixed to the other surface of the double-faced adhesive member 60 by bonding.

As illustrated in FIGS. 4 and 5, the transparent plate member 33 is formed by a rectangular transparent resin panel, and is located corresponding to the position of the time display section 21 serving as the display section. Through the transparent plate member 33, the time display section 21 provided in the movable rear case 30 to display predetermined information can be viewed. The transparent plate member 33 is located in a cutout portion 37 provided in a part of the metal panel member 35. That is, the cutout portion 37 is an area where the transparent plate member 33 is located. The transparent plate member 33 is sized such as to have a width substantially equal to that of the cutout portion 37.

As the transparent plate member 33, a hardened glass member having a predetermined strength may be used instead of the transparent resin panel.

A rectangular thin metal panel is used as the metal panel member 35. The front surface of the metal panel member 35 is coated with a thin resin material. The metal panel member 35 is a member that covers portions other than the area where the transparent plate member 33 is located.

As described above, the cutout portion 37 serving as the area where the transparent plate member 33 is located is provided in a part of the metal panel member 35. The transparent plate member 33 and the metal panel member 35 are fixed to the metal frame plate 50 of the movable rear case 30 with the double-faced adhesive member 60 therebetween while being bonded to the upper surface of the double-faced adhesive member 60, as illustrated by diagonal lines in FIG. 9.

The metal frame plate 50 is a metal frame member having the same rectangular shape as that of the movable rear case 30 and having a width slightly smaller than the width of the movable rear case 30. As illustrated in FIG. 8, a plurality of openings 52, 53, and 54 are provided at predetermined positions in a main portion 51 of the metal frame plate 50, and electric components and the like provided in the movable rear case 30 are placed therein.

The double-faced adhesive member 60 is an adhesive sheet member having the same rectangular shape as that of the metal frame plate 50 and having a width substantially equal to the width of the metal frame plate 50. As illustrated in FIG. 8, a plurality of openings 62, 63, and 64 are also provided at positions in a main portion 61 of the double-faced adhesive member 60 corresponding to the openings 52, 53, and 54 provided in the metal frame plate 50.

As illustrated in FIG. 9, the double-faced adhesive member 60 is bonded with its lower surface in contact with the upper surface of the metal frame plate 50. By thus interposing the double-faced adhesive member 60 serving as a waterproof sheet between the front panel plate 32 and the metal frame plate 50, the interior of the movable housing 20 of the mobile telephone 1 is made waterproof.

More specifically, one of the adhesive surfaces on both sides of the double-faced adhesive member 60 is fixed to the upper surface of the metal frame plate 50 by bonding, and the lower surfaces of the transparent plate member 33 and the metal panel member 35 that constitute the front panel plate 32 are fixed to the other adhesive surface by bonding. The transparent plate member 33 and the metal panel member 35 are provided to ensure a predetermined width (e.g. 2 mm) of bonding to the double-faced adhesive member 60.

A bonding area diagonally shaded in FIG. 8, of the entire bonding area of the double-faced adhesive member 60, is provided as a dual-purpose bonding area that serves as both a metal-panel bonding area where the lower surface of the metal panel member 35 is fixed to a predetermined position on the metal frame plate 50 by bonding and a transparent-plate-member bonding area where the lower surface of the transparent plate member 33 is fixed to a predetermined position on the metal frame plate 50 by bonding. For this reason, the width T of the dual-purpose bonding area is double the above-described predetermined width (e.g. 4 mm). In this way, both the transparent plate member 33 and the metal panel member 35 can thus be fixed to the metal frame plate 50 provided in the movable rear case 30 by bonding using the single double-faced adhesive member 60. This can reduce the number of components.

As described above, in the mobile telephone 1 of the embodiment, the metal frame plate 50 formed by a metal plate is provided in the movable rear case 30 of the movable housing 20 in the mobile telephone 1, and the transparent plate member 33 and the metal panel member 35 are combined into the front panel plate 32 at a predetermined position and are fixed onto the upper surface of the metal frame plate 50 with the double-faced adhesive member 60 formed by the waterproof sheet disposed therebetween. This can improve the strength and waterproofness of the movable housing 20 in the mobile telephone 1.

The time display section 21 provided under the transparent plate member 33 in the surface panel plate 32 can be viewed through the transparent plate member 33, and the transparent plate member 33 and the metal panel member 35 that define the front panel plate 32 can be fixed to the metal frame plate 50 with the single double-faced adhesive member 60 disposed therebetween. Moreover, a part of the bonding area of the double-faced adhesive member 60 can be used to fix both the transparent plate member 33 and the metal panel member 35 by bonding. The number of components is thereby reduced.

### Other Embodiments

While the embodiment has been described above, the mobile terminal device disclosed in this application can be carried out not only by the above-described embodiment, but also by various different embodiments without departing from the scope of the technical idea described in the above claims.

That is, while the mobile terminal device is applied to the mobile telephone foldable on the hinge portion in the above-described embodiment, it is also applicable not only to the illustrated hinge structure, but also various hinge structures. Further, the mobile terminal device is similarly applicable not only to the folding type using the hinge structure, but also to a case in which the movable housing can be placed on the fixed housing with a connecting portion of, for example, a slide type or an in-plane rotation type.

In addition, the mobile terminal device is also applicable to other various mobile terminal devices, for example, a small information processing terminal such as a PDA (Personal Digital Assistant), a small music player, a mobile television, and a mobile game machine.

The disclosed mobile terminal device can improve waterproofness and strength of the housing. Further, the disclosed mobile terminal device can realize thickness reduction and allows viewing of the information display section.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present inventions have been described in detail, it should be understood that the various changes, substitutions, and alterations could be made hereto without departing from the spirit and scope of the invention.

What is claimed is:

1. A mobile terminal device comprising:
a display section;
a housing including a frame member forming an opening for accommodating the display section;
a transparent plate member disposed over the display section;
a metal panel member disposed over the frame member so as to expose the transparent plate member; and
an adhesive member having an adhesive obverse surface and an adhesive reverse surface placed between the frame member and each of the transparent plate member and the metal panel member, the adhesive reverse surface being adhesively fixed to the frame member, the adhesive obverse surface being adhesively fixed to the transparent plate member and the metal panel member.

2. The mobile terminal device according to claim 1, wherein a part of the adhesive reverse surface is provided as a first bonding area fixing the transparent plate member to a predetermined position of the frame member, and another part of the adhesive reverse surface is provided as a second bonding area fixing the metal panel member to another predetermined position of the frame member.

3. The mobile terminal device according to claim 1, wherein the adhesive reverse surface includes a dual-purpose bonding area fixing the metal panel member to a predetermined position of the frame member and fixing the transparent plate member to another predetermined position of the frame member.

4. The mobile terminal device according to claim 1, wherein the metal panel member forms a cutout portion where the transparent plate member is disposed.
